(19) United States
(12) Patent Application Publication
(10) Pub. No.: US 2026/0163555 A1
(43) Pub. Date: Jun. 11, 2026

(54) LIQUID CRYSTAL PHASE SHIFTER AND PHASED ARRAY ANTENNA

(71) Applicants: Beijing BOE Technology Development Co., Ltd., Beijing (CN); BOE Technology Group Co., Ltd., Beijing (CN)

(72) Inventors: Jia FANG, Beijing (CN); Feng QU, Beijing (CN)

(21) Appl. No.: 18/709,799

(22) PCT Filed: Aug. 28, 2023
(86) PCT No.: PCT/CN2023/115227

§ 371 Date: May 13, 2024

(51) Int. Cl. H03H 11/16; H01Q 3/36

(52) U.S. Cl. CPC H03H 11/16; H01Q 3/36

(57) ABSTRACT

The present disclosure provides a liquid crystal phase shifter and a phased array antenna. The liquid crystal phase shifter includes: a liquid crystal phase shift unit and a switch phase shift unit, where a second end of the liquid crystal phase shift unit is electrically connected to a first end of the switch phase shift unit; a target phase difference between a signal transmitted from a second end of the switch phase shift unit and a signal transmitted from a first end of the liquid crystal phase shift unit is within [0, 360°]; and the switch phase shift unit is configured to determine a phase change range of a signal transmitted from the liquid crystal phase shifter; the liquid crystal phase shift unit is configured to continuously adjust, within the phase change range, a phase of the signal transmitted from the liquid crystal phase shifter to the target phase difference.

### TECHNICAL FIELD

The present disclosure relates to the field of control technology, and in particular, to a liquid crystal phase shifter and a phased array antenna.

### BACKGROUND

The phased array antenna is provided with a phase shifter, and the phase shifter is used for adjusting a microwave phase to realize the effect on adjusting and controlling a beam direction.

In the related art, the phase shifter is implemented by a liquid crystal phase shifter, and a phase of a signal transmitted from the phase shifter may be continuously adjusted by changing a dielectric constant of liquid crystals in the phase shifter. However, an adjustable range of the dielectric constant of liquid crystals is smaller, and a phase shifter with a larger size is required to achieve a 360° phase difference, resulting in a higher loss of the liquid crystal phase shifter.

### SUMMARY

The present disclosure provides a liquid crystal phase shifter and a phased array antenna to solve the above technical problem.

According to a first aspect of the present disclosure, there is provided a liquid crystal phase shifter, including: a liquid crystal phase shift unit and a switch phase shift unit, where a second end of the liquid crystal phase shift unit is electrically connected to a first end of the switch phase shift unit; a target phase difference between a signal transmitted from a second end of the switch phase shift unit and a signal transmitted from a first end of the liquid crystal phase shift unit is within [0°, 360°]; and
the switch phase shift unit is configured to determine a phase change range of a signal transmitted from the liquid crystal phase shifter; the liquid crystal phase shift unit is configured to continuously adjust, within the phase change range, a phase of the signal transmitted from the liquid crystal phase shifter to the target phase difference.

Optionally, the liquid crystal phase shift unit includes: a CPW liquid crystal phase shifter, a differential liquid crystal phase shifter, a microstrip line liquid crystal phase shifter, an inverted microstrip line liquid crystal phase shifter, or any combination thereof.

Optionally, the differential liquid crystal phase shifter comprises a signal synthesizer; wherein the signal synthesizer is configured to synthesize signals respectively transmitted from signal paths of the differential liquid crystal phase shifter to obtain a synthesized signal; and the signals respectively transmitted from the signal paths have a phase difference.

Optionally, the signal synthesizer includes a power divider or a balun device.

Optionally, the liquid crystal phase shift unit includes a first substrate, a first metal layer, liquid crystals, a second metal layer and a second substrate that are arranged in sequence; the first metal layer and the second metal layer are opposite to each other, and are configured to continuously adjust directions of the liquid crystals, so as to adjust a phase of a signal.

Optionally, a thickness of the first substrate and/or the second substrate is [100, 10000] μm.

Optionally, the first substrate and/or the second substrate include(s) a through hole; the through hole is configured to electrically connect a switch chip of the switch phase shift unit to a pattern portion of the switch phase shift unit; and the pattern portion of the switch phase shift unit is located in a liquid crystal cell of the liquid crystal phase shift unit.

Optionally, a ratio of a diameter of the through hole to a thickness of the first substrate or the second substrate is [1:3, 3:1].

Optionally, the first metal layer of the liquid crystal phase shift unit includes a first pattern, and the first pattern includes a plurality of metal wires arranged according to a first direction; the second metal layer of the liquid crystal phase shift unit includes a second pattern, and the second pattern includes a plurality of metal wires arranged according to a second direction; where the first direction is perpendicular to the second direction; the metal wires in the first pattern and the metal wires in the second pattern are opposite to each other; a pattern portion of the switch phase shift unit is arranged on a same layer as the second pattern of the liquid crystal phase shift unit, and is electrically connected to the second pattern of the liquid crystal phase shift unit through a switch chip of the switch phase shift unit.

Optionally, the first metal layer of the liquid crystal phase shift unit includes a third pattern, and the second metal layer of the liquid crystal phase shift unit includes a fourth pattern; and
toothed bars of a first comb-shaped portion of the third pattern and toothed bars of a second comb-shaped portion of the fourth pattern are opposite to each other; a first handle portion of the third pattern and a second handle portion of the fourth pattern form a path with a preset phase difference.

Optionally, a pattern portion of the switch phase shift unit is arranged on a same layer as the fourth pattern of the liquid crystal phase shift unit, and is electrically connected to the fourth pattern of the liquid crystal phase shift unit through a switch chip of the switch phase shift unit.

Optionally, the switch phase shift unit includes at least one switch chip, and the at least one switch chip is fixed to the second substrate; the at least one switch chip of the switch phase shift unit is configured to select any one path of the pattern portion of the switch phase shift unit.

Optionally, a switch chip of the switch phase shift unit is arranged in a liquid crystal cell of the liquid crystal phase shift unit.

Optionally, the switch chip is fixed to a cell bottom of the liquid crystal cell, a cell top of the liquid crystal cell or a cell inner side of the liquid crystal cell.

Optionally, the switch chip is implemented by:
a single-input single-output switch, a single-input double-output switch, a single-output double-input switch, a single-input three-output switch, a single-output three-input switch, a single-input four-output switch, a single-output four-input switch, or any combination thereof.

Optionally, a groove is provided at a position of the first substrate of the liquid crystal phase shift unit corresponding to the switch phase shift unit, and the groove matches the liquid crystal cell.

Optionally, the liquid crystal phase shift unit includes a third substrate, and the third substrate is arranged between the first substrate and the first metal layer; a through hole is provided at a position of the third substrate corresponding to the switch phase shift unit, and the through hole matches the liquid crystal cell.

Optionally, a through hole is provided at a position of the first substrate of the liquid crystal phase shift unit corresponding to the switch phase shift unit, and the through hole matches the liquid crystal cell.

Optionally, the switch chip of the switch phase shift unit is integrally manufactured with the liquid crystal phase shift unit.

Optionally, the switch chip includes an MEMS switch chip and/or a PIN switch chip, and the MEMS switch chip and/or the PIN switch chip is fixed to the liquid crystal phase shifter.

Optionally, the switch chip of the switch phase shift unit is an MEMS switch; the MEMS switch is implemented by a cantilever beam structure; a first end of the cantilever beam structure is electrically connected to a first control line, and a second end of the cantilever beam structure is electrically connected to a second control line; when a voltage difference exists between the first end and the second end of the cantilever beam structure, a movable contact of the cantilever beam structure is in contact with a stationary contact of the cantilever beam to change a signal transmission path.

Optionally, the MEMS switch is implemented by a membrane structure; a first end of the membrane structure is electrically connected to a first control line, and a second end of the membrane structure is electrically connected to a second control line; when a voltage difference exists between the first end and the second end of the membrane structure, a membrane of the membrane structure is deformed to change a signal transmission path.

Optionally, a phase shift range of the liquid crystal phase shift unit is [0, 180°], and a phase shift angle of the switch phase shift unit is a value of {0°, 180°}; or
a phase shift range of the liquid crystal phase shift unit is [0°, 90°], and a phase shift angle of the switch phase shift unit is a value of {0°, 90°, 180°, 270°}; or
a phase shift range of the liquid crystal phase shift unit is [0°, 270°], and a phase shift angle of the switch phase shift unit is a value of {0°, 90°}.

According to a second aspect of the present disclosure, there is provided a phased array antenna, including: radiation devices arranged in an array, and liquid crystal phase shifters according to the first aspect respectively corresponding to the radiation devices, where the liquid crystal phase shifters are electrically connected to the radiation devices; where
each of the liquid crystal phase shifters is configured to shift a phase of an input signal to obtain a phase shifted signal; and
each of the radiation devices is configured to receive an electromagnetic wave from a space, convert the electromagnetic wave into a to-be-phase-shifted input signal, and transmit the to-be-phase-shifted input signal to the liquid crystal phase shifter; or each of the radiation devices is configured to convert the phase shifted signal from the liquid crystal phase shifter into an electromagnetic wave signal, and radiate the electromagnetic wave signal to a space.

Optionally, a fourth substrate and a third metal layer are further included, where the radiation device is arranged on a first side of the fourth substrate; the third metal layer is formed on a second side of the fourth substrate; the third metal layer is located between the fourth substrate and a first substrate of the liquid crystal phase shifter; the third metal layer is provided with a radiation hole.

Optionally, a feed network and a fifth substrate are further included, where the feed network is arranged between the fifth substrate and a second substrate of the liquid crystal phase shifter, and is configured to radiate an original signal to the liquid crystal phase shifter for phase shift or receive the phase shifted signal output from the liquid crystal phase shifter.

Optionally, the radiation device includes a feed selection circuit;
when the feed selection circuit is in a first path, a circular polarization direction of the phased array antenna is one of a left-hand direction or a right-hand direction;
when the feed selection circuit is in a second path, the circular polarization direction of the phased array antenna is another one of the left-hand direction or the right-hand direction.

Optionally, the feed selection circuit includes a first feed line, a second feed line, a third feed line, a first feed switch, a second feed switch, and a third feed switch; a first end of the first feed switch is electrically connected to the first feed line, a second end of the first feed switch is electrically connected to the second feed line, and a third end of the first feed switch is electrically connected to the third feed line; a first end of the second feed switch is electrically connected to the first feed line, and a second end of the second feed switch is electrically connected to a radiation patch of the radiation device; a first end of the third feed switch is electrically connected to the second feed line, and a second end of the third feed switch is electrically connected to the radiation patch; the radiation hole of the third metal layer is opposite to the third feed line;
when the first end and the third end of the first feed switch are electrically connected, and the second feed switch is turned on, the feed selection circuit is in the first path;
when the second end and the third end of the first feed switch are electrically connected, and the third feed switch is turned on, the feed selection circuit is in the second path.

Optionally, switches in the liquid crystal phase shifter and switches in the feed selection circuit are implemented by field effect transistors.

According to a third aspect of the present disclosure, there is provided a communication device, including: the phased array antenna according to the second aspect.

The technical solutions provided in the embodiments of the present disclosure may include the following beneficial effects:

The liquid crystal phase shifter in the solutions of the embodiments includes: a liquid crystal phase shift unit and a switch phase shift unit, where a second end of the liquid crystal phase shift unit is electrically connected to a first end of the switch phase shift unit; a target phase difference between a signal transmitted from a first end of the liquid crystal phase shift unit and a signal transmitted from a second end of the switch phase shift unit is located within [0, 360°]; the switch phase shift unit is configured to determine a phase change range of a signal transmitted from the liquid crystal phase shifter; the liquid crystal phase shift unit is configured to continuously adjust a difference between a phase of the signal transmitted from the liquid crystal phase shifter and a target phase within the phase change range. In this way, the phase change range of the liquid crystal phase shifter in the embodiments is selected through the switch phase shift unit, and a phase of the liquid crystal phase shift unit is continuously adjusted. On the basis of satisfying a phase shift range of [0, 360°] and a higher resolution, a size of the liquid crystal phase shift unit can be reduced, achieving the goal of reducing a loss of the liquid crystal phase shifter.

It should be understood that the above general description and the following detailed description are only exemplary and explanatory and are not restrictive of the present disclosure.

### BRIEF DESCRIPTION OF DRAWINGS

FIG. 1 is a block diagram of a liquid crystal phase shifter according to an embodiment of the present disclosure.

FIG. 2 is a structural schematic diagram of a liquid crystal phase shifter according to an embodiment of the present disclosure.

FIG. 3 is a structural schematic diagram of a liquid crystal phase shifter according to an embodiment of the present disclosure.

FIG. 4 is a structural schematic diagram of another liquid crystal phase shifter according to an embodiment of the present disclosure.

FIG. 5 is a cross-sectional view of a through hole according to an embodiment of the present disclosure.

FIG. 6 is a cross-sectional view of another through hole according to an embodiment of the present disclosure.

FIG. 7 is a structural schematic diagram of another liquid crystal phase shifter according to an embodiment of the present disclosure.

FIG. 8 is a structural schematic diagram of another liquid crystal phase shifter according to an embodiment of the present disclosure.

FIG. 9 is a structural schematic diagram of another liquid crystal phase shifter according to an embodiment of the present disclosure.

FIG. 10 is a structural schematic diagram of another liquid crystal phase shifter according to an embodiment of the present disclosure.

FIG. 11 is a structural schematic diagram of a switch phase shift unit according to an embodiment of the present disclosure.

FIG. 12 is a structural schematic diagram of a switch phase shift unit according to an embodiment of the present disclosure.

FIG. 13 is a structural schematic diagram of a switch phase shift unit according to an embodiment of the present disclosure.

FIG. 14 is a structural schematic diagram of a switch phase shift unit according to an embodiment of the present disclosure.

FIG. 15 is a schematic diagram of a phase change range of a liquid crystal phase shifter according to an embodiment of the present disclosure.

FIG. 16 is a schematic diagram of a phase change range of another liquid crystal phase shifter according to an embodiment of the present disclosure.

FIG. 17 is a schematic diagram of a phase change range of another liquid crystal phase shifter according to an embodiment of the present disclosure.

FIG. 18 is a structural schematic diagram of a phased array antenna according to an embodiment of the present disclosure.

FIG. 19 is a structural schematic diagram of a radiation device according to an embodiment of the present disclosure.

FIG. 20 is a structural schematic diagram of a phased array antenna according to an embodiment of the present disclosure.

FIG. 21 is a structural schematic diagram of another phased array antenna according to an embodiment of the present disclosure.

### DETAILED DESCRIPTION

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses consistent with some aspects of the present disclosure as detailed in the appended claims.

In the related art, the phase shifter is implemented by a liquid crystal phase shifter, and a phase of a signal transmitted from the phase shifter may be continuously adjusted by changing a dielectric constant of liquid crystals in the phase shifter. However, an adjustable range of the dielectric constant of liquid crystals is smaller, and a phase shifter with a larger size is required to achieve a 360° phase difference, resulting in a higher loss of the liquid crystal phase shifter. In an example, a Figure of Merit (FoM) of the liquid crystal phase shifter is about 120°/dB, and when the liquid crystal phase shifter has a phase shift of 360°, its power loss is about 3 dB, which reduces the efficiency of the entire phased array antenna.

In order to solve the above technical problem, embodiments of the present disclosure provide a liquid crystal phase shifter and a phased array antenna.

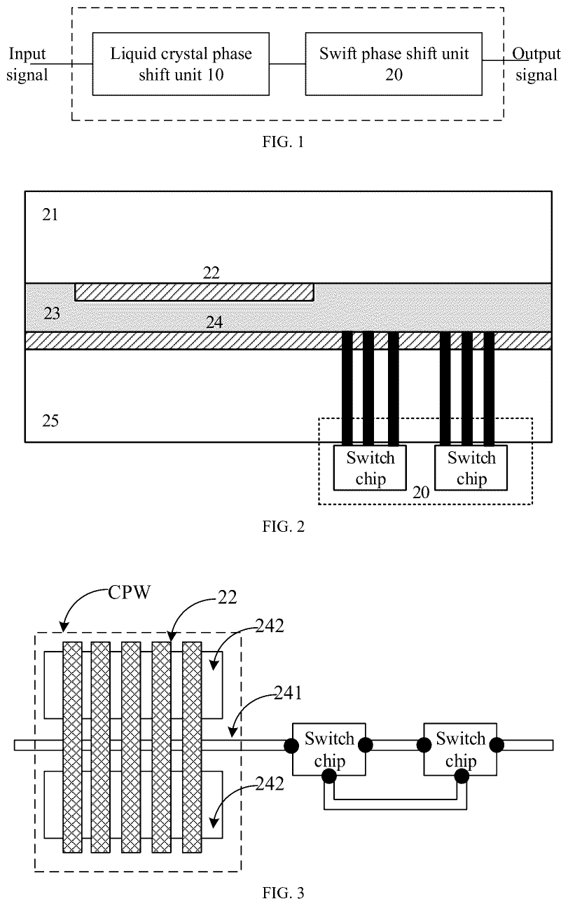

Referring to FIG. 1, a liquid crystal phase shifter includes a liquid crystal phase shift unit 10 and a switch phase shift unit 20. A second end of the liquid crystal phase shift unit 10 is electrically connected to a first end of the switch phase shift unit 20; a target phase difference between a signal transmitted from a second end of the switch phase shift unit 20 and a signal transmitted from a first end of the liquid crystal phase shift unit 10 is within [0°, 360°]; the switch phase shift unit 20 is configured to determine a phase change range of a signal transmitted from the liquid crystal phase shifter; the liquid crystal phase shift unit 10 is configured to continuously adjust, within the phase change range, a phase of the signal transmitted from the liquid crystal phase shifter to a target phase difference. The target phase difference may be determined according to a beam direction of a subsequent phased array antenna, which will not be described here.

In an embodiment, referring to FIG. 2, the liquid crystal phase shift unit 10 includes a first substrate 21, a first metal layer 22, liquid crystals 23, a second metal layer 24 and a second substrate 25. The first metal layer 22 and the second metal layer 24 are arranged opposite to each other. It can be understood that, when the first metal layer 22 and the second metal layer 24 are opposite to each other, a coupling capacitor may be formed between the two metal layers, an electric field may be formed between two electrode plates of the coupling capacitor, and the electric field changes directions of the liquid crystals; when the directions of the liquid crystals are different, a dielectric constant of the coupling capacitor is changed therewith. In this way, a phase of a signal transmitted from the second metal layer 24 is changed. The switch phase shift unit 20 includes switch chips 26, and different transmission paths in the second metal layer 24 may be switched by the switch chips 26. Phase change ranges of signals in different transmission paths are different, which will be continuously described later, but will not be described here.

In an embodiment, the liquid crystal phase shift unit 10 may include at least one of the following: a CPW (Coplanar Waveguide) liquid crystal phase shifter, a differential liquid crystal phase shifter, a microstrip line liquid crystal phase shifter, or an inverted microstrip line liquid crystal phase shifter. Those skilled in the art may select a corresponding liquid crystal phase shift unit according to a specific scenario, and in a case where continuous phase shifts can be implemented, corresponding solutions fall within the protection scope of the present disclosure.

In an example, the liquid crystal phase shift unit 10 may be implemented by using a CPW liquid crystal phase shifter. The first metal layer of the CPW liquid crystal phase shift unit includes a first pattern, and the first pattern includes a plurality of metal wires arranged according to a first direction, where the number of the metal wires in the first pattern may be set according to a specific scenario; the second metal layer of the liquid crystal phase shift unit includes a second pattern, and the second pattern includes a plurality of metal wires arranged according to a second direction, where the number of the metal wires in the second pattern may be set according to a specific scenario; the first direction is perpendicular to the second direction; the metal wires in the first pattern and the metal wires in the second pattern are arranged opposite to each other.

Referring to FIG. 3, the first metal layer 22 of the CPW liquid crystal phase shifter includes metal wires vertically arranged up and down, that is, a plurality of metal wires are arranged in a column direction, 5 metal wires are shown in FIG. 3, and the first direction is a vertical direction (or an up and down direction) shown in FIG. 3; the second metal layer 24 of the CPW liquid crystal phase shifter includes a first metal wire 241 and second metal wires 242, and a width of the first metal wire 241 is less than a width of the second metal wire 242. The width of the second metal wire 242 is greater than or equal to a first preset width, so that an area of the second metal wires 242 facing the metal wires in the first metal layer 22 can be increased, that is, a capacitance value of the coupling capacitor or an area of an electromagnetic field applied to the liquid crystals can be increased, which is beneficial to increasing a phase shift change range of the liquid crystal phase shifter. The second metal wires 242 may be arranged on both sides (an upper side and a lower side in FIG. 3) of the first metal wire 241, so that an electromagnetic field is formed between the second metal wires 242 and the first metal wire 241. In an example, the width of the first metal wire 241 may be reduced and the width of the second metal wire 242 may be increased, which further increases a width difference between the second metal wire 242 and the first metal wire 241, increasing an area of the electromagnetic field. When a voltage difference between the first metal layer 22 and the second metal layer 24 is changed, directions of liquid crystals are changed therewith, which causes a dielectric constant of the coupling capacitor to be changed. When the dielectric constant of the coupling capacitor is changed, a phase of a signal transmitted from the first metal wire 241 is changed.

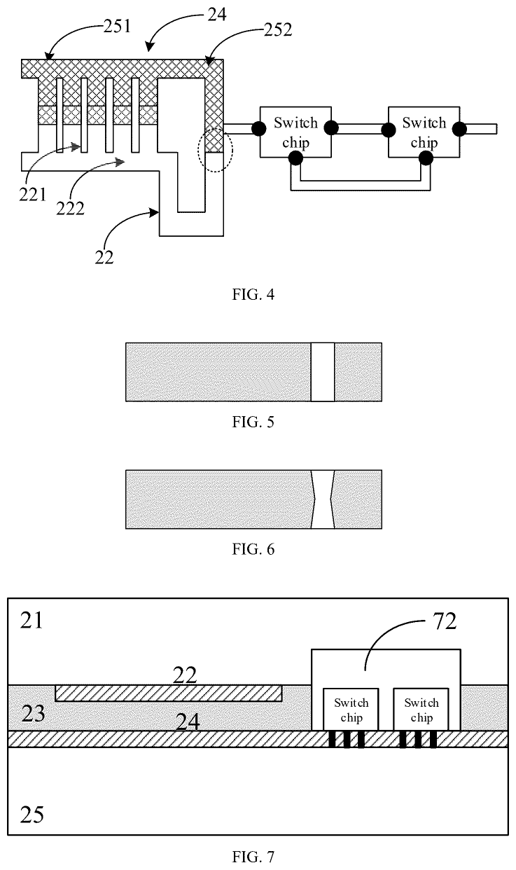

In an example, the liquid crystal phase shift unit 10 may be implemented by a differential liquid crystal phase shifter. The first metal layer of the liquid crystal phase shift unit includes a third pattern, and the second metal layer of the liquid crystal phase shift unit includes a fourth pattern; toothed bars of a first comb-shaped portion of the third pattern and toothed bars of a second comb-shaped portion of the fourth pattern are directly opposite to each other, and a first handle portion of the third pattern and a second handle portion of the fourth pattern form a path with a phase difference, for example, the phase difference may be 180°, and may be set according to a specific scenario. Referring to FIG. 4, the first metal layer 22 of the differential liquid crystal phase shifter includes a third pattern, and the second metal layer 24 of the differential liquid crystal phase shifter includes a fourth pattern. Toothed bars of a first comb-shaped portion 221 of the third pattern and toothed bars of a second comb-shaped portion 251 of the fourth pattern are opposite to each other, and a first handle portion 222 of the third pattern and a second handle portion 252 of the fourth pattern form a signal transmission path with a phase difference of 180°. In other words, when the toothed bars of the first comb-shaped portion 221 in the third pattern and the toothed bars of the second comb-shaped portion 251 in the fourth pattern are opposite to each other, a coupling capacitor is formed, and the larger an area of the toothed bars of the first comb-shaped portion 221 in the third pattern opposite to the toothed bars of the second comb-shaped portion 251 in the fourth pattern is, the greater a capacitance value of the coupling capacitor is. When a voltage difference is applied between two electrodes of the coupling capacitor, directions of liquid crystals in the coupling capacitor can be adjusted, and thereby a dielectric constant of the coupling capacitor can be adjusted. When the dielectric constant of the coupling capacitor is changed, a phase of a signal transmitted from the first metal layer 22 can be changed.

In this example, the differential liquid crystal phase shifter includes a signal synthesizer (not shown in the figure). The signal synthesizer is configured to synthesize signals respectively transmitted from signal paths of the differential liquid crystal phase shifter to obtain a synthesized signal; the signals respectively transmitted from signal paths have a phase difference. Still referring to FIG. 4, considering that a phase difference of a same signal passing through two signal transmission paths of the differential liquid crystal phase shifter is 180°, the signal may be synthesized into a synthesized signal through the signal synthesizer. In some possible examples, the signal synthesizer may include a power divider or a balun device, and the signal synthesizer may be arranged at a location of a dashed box in FIG. 4.

In an embodiment, the first metal layer 22 and the second metal layer 24 may be made of a low-resistance and low-loss metal material such as copper, gold, silver or aluminium, and through at least one of magnetron sputtering, thermal evaporation or electroplating, which may be set according to a specific scenario.

In an embodiment, the first substrate 21 and the second substrate 25 may be made of a PCB insulating plate such as a polytetrafluoroethylene glass fiber pressing plate, a phenolic paper laminate, or a phenolic glass cloth laminate, or of a material with a lower loss such as quartz or glass. A thickness of the first substrate 21 and/or the second substrate 25 is [100, 10000] μm, and may be set according to a specific scenario.

In some possible examples, the first substrate 21 and/or the second substrate 25 include(s) a through hole; a metallized through hole may be used as the through hole or the through hole may be filled with metal. A ratio of a diameter of the through hole to a thickness of the first substrate 21 or the second substrate 25 is [1:3, 3:1]. In an example, the ratio of the diameter of the through hole to the thickness of the first substrate 21 or the second substrate 25 is 1:1. In some examples, referring to FIG. 5, a cross section of the through hole is circular, that is, the through hole is a hollow cylinder; or referring to FIG. 6, a cross section at an opening of the through hole is larger than a cross section at a waist of the through hole, that is, the through hole is a hollow sand glass. The liquid crystal phase shift unit 10 and the switch phase shift unit 20 are electrically connected through the through hole. As shown in FIGS. 2, 3 and 4, taking that the second substrate 25 is provided with a through hole as an example, a second side (a lower side as shown in FIG. 2) of the second substrate 25 is provided with a plurality of bonding pads, and the number of the bonding pads may be set according to a number of pins of a switch chip in the switch phase shift unit, where each pin corresponds to one bonding pad. The second metal layer 24 may be electrically connected to the bonding pads through metal passing through the second metal layer. Specifically, a pattern portion of the switch phase shift unit located in the second metal layer 24 includes at least two paths with different phases, and the paths may be switched through a switch chip. Still referring to FIG. 3, the switch chip on a left side includes three pins, and the three pins are respectively connected to the first metal wire 241, a first path (between two switch chips), and a (U-shaped) second path. When the switch chip is switched to the first path, the first metal wire 241 is electrically connected to the first path. When the switch chip is switched to the second path, the first metal wire 241 is electrically connected to the second path. The switch chip on a right side includes three pins, and the three pins are respectively connected to an extension line of the first metal wire 241, a first path (between two switch chips), and a (U-shaped) second path. When the switch chip is switched to the first path, the extension line of the first metal wire 241 is electrically connected to the first path. When the switch chip is switched to the second path, the extension line of the first metal wire 241 is electrically connected to the second path. When the two switch chips are connected to the first path at the same time, the switch phase shift unit may shift a phase by 0°, and when the two switch chips are connected to the second path at the same time, the switch phase shift unit may shift a phase by 90° or 180°, which may be set according to a specific scenario. That is, in this embodiment, by adjusting the diameter and the shape of the through hole, the reliability of electrical connection between the liquid crystal phase shift unit 10 and the switch phase shift unit 20 can be ensured.

In an embodiment, the switch phase shift unit 20 includes switch chips. The switch chips are fixed to bonding pads of the second substrate 25 through Surface Mounted Technology (SMT), and the bonding pads are electrically connected to the second metal layer through a through hole in the second substrate 25 of the liquid crystal phase shifter, that is, the switch chips are electrically connected to a pattern portion of the switch phase shift unit 20.

In an example, the switch chip may include an MEMS switch chip and/or a PIN switch chip, and the switch chip may be implemented by at least one of the following: a single-input single-output switch, a single-input double-output switch, a single-output double-input switch, a single-input three-output switch, a single-output three-input switch, a single-input four-output switch, or a single-output four-input switch. For ease of description, in subsequent embodiments, the switch chip is implemented by a single-input double-output switch or a single-input multiple-output switch, that is, the switch chip with a lower microwave loss is selected to improve FoM of the phase shifter. In this embodiment, the switch chip may be fixed to the liquid crystal phase shifter through SMT. In this way, in this example, the switch phase shift unit 20 is electrically connected to the liquid crystal phase shift unit 10 through SMT, and the solution is simple and easy to implement.

In another embodiment, referring to FIG. 7, the switch chips of the switch phase shift unit are arranged in a liquid crystal cell of the liquid crystal phase shift unit, so that there is no need to provide a through hole, which improves the reliability of electrical connection between the switch phase shift unit 20 and the liquid crystal phase shift unit 10. The switch chips may be fixed to at least one position of a cell bottom, a cell top or a cell inner side of the liquid crystal cell. The position of the switch chips may be set according to a specific scenario, and corresponding solutions fall within the protection scope of the present disclosure.

In an embodiment, still referring to FIG. 7, a groove 72 is provided at a position of the first substrate 21 of the liquid crystal phase shift unit corresponding to the switch phase shift unit, and the groove 72 matches the liquid crystal cell (not shown), that is, after the first substrate 21 and the second substrate 25 are buckled, the liquid crystal cell may be embedded into the groove 72, and a portion of the switch chip being higher than a thickness of the liquid crystal cell may be embedded into the groove 72, which satisfies a scenario where a height of the switch chip exceeds the thickness of the liquid crystal cell.

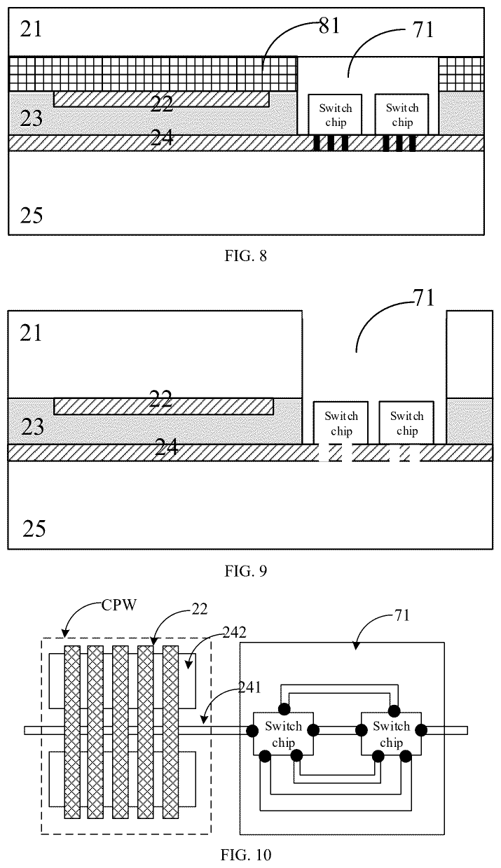

In an embodiment, referring to FIG. 8, the liquid crystal phase shift unit 10 further includes a third substrate 81, and the third substrate 81 is arranged between the first substrate 21 and the first metal layer 22. A through hole 71 is provided at a position of the third substrate 81 corresponding to the switch phase shift unit, and a shape of the through hole 71 matches a shape of the liquid crystal cell. That is, the first substrate 21, the third substrate 81 and the second metal layer 24 together form a space for accommodating the liquid crystal cell, which ensures that the switch chips of the switch phase shift unit are located in the liquid crystal cell. In this way, in this embodiment, the third substrate 81 may be separately etched to form a through hole with a shape similar to the shape of the through hole shown in FIG. 5, so as to reduce an area of the through hole as much as possible, and ensure a support force of the first substrate 21, which is beneficial to improving the yield of a manufacturing process.

In an embodiment, referring to FIG. 9, a through hole is provided at a position of the first substrate 21 of the liquid crystal phase shift unit 10 corresponding to the switch phase shift unit 20, and the through hole matches the liquid crystal cell. That is, when the liquid crystal phase shift unit is observed from a top view, the switch chips of the switch phase shift unit 20 can be directly seen, the effect of which is shown in FIG. 10. In this embodiment, the first substrate 21 may be etched to form the through hole 71, and then buckled onto the second substrate 25, so that bonding pads for fixing the switch chips are seen from the top view; next, the switch chips may be soldered to the bonding pads. In some possible examples, after the switch chips are soldered to the bonding pads, a planarization layer may be further formed, and the planarization layer is implemented by using an insulating material, so as to achieve the effect on filling the through hole 71; and the planarization layer may be reused to be waterproof, anti-static, etc., achieving the goal of ensuring the switching chips.

In this embodiment, when the switch chips of the switch phase shift unit are arranged in the liquid crystal cell, the switch chips may be integrally manufactured with the liquid crystal phase shift unit 10, which is beneficial to improving the yield of the liquid crystal phase shifter. For example, the switch chip is made of a field effect transistor, and the field effect transistor includes a gate layer (GE), a source layer (SD1) and a drain layer (SD2); the first metal layer and the second metal layer in the liquid crystal phase shift unit may be respectively designed on a same layer as the source layer (SD1) and the drain layer (SD2), and the gate layer may be arranged at the through hole 71 of the first substrate, so as to achieve the effect on manufacturing the liquid crystal phase shift unit and the switch phase shift unit by an existing production technology. For another example, the switch chips may be implemented by using an MEMS (Micro-Electro-Mechanical System) switch in a subsequent embodiment, and at this point, in a process of manufacturing the liquid crystal phase shift unit, a process step of generating the MEMS switch is added, so as to achieve the effect on integrally manufacturing the liquid crystal phase shift unit and the switch phase shift unit.

In an example, the switch phase shift unit 20 may include an MEMS switch or a PIN (Positive Intrinsic Negative) switch, or may be implemented by an MEMS switch device with a glass substrate, which may be selected according to a specific scenario, and in a case where paths with different phase differences can be selected, corresponding solutions fall within the protection scope of the present disclosure.

For ease of description of solutions, taking the switch phase shift unit 20 being an MEMS switch as an example, the MEMS switch may be implemented by a cantilever beam structure or a membrane structure.

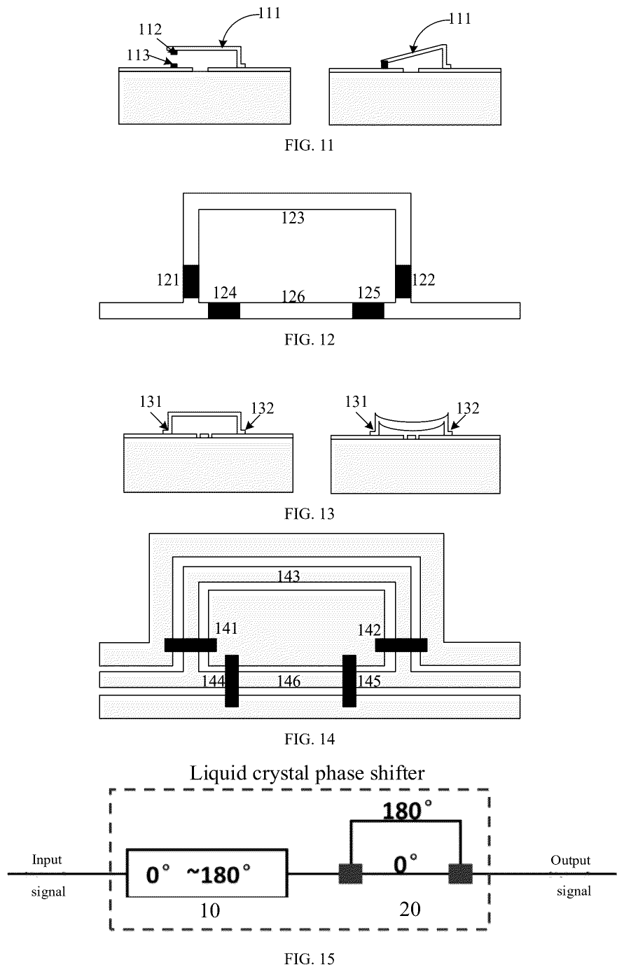

Taking the MEMS switch being implemented by a cantilever beam structure as an example, referring to FIG. 11, a first end of the cantilever beam structure 111 is electrically connected to a first control line (not shown in the figure), and a second end of the cantilever beam structure 111 is electrically connected to a second control line (not shown in the figure); when a voltage difference exists between the first end and the second end of the cantilever beam structure 111, a movable contact 112 of the cantilever beam structure 111 is in contact with a stationary contact 113, and the MEMS switch is turned on to change a signal transmission path; when the movable contact 112 of the cantilever beam structure 111 is not in contact with the stationary contact 113, the MEMS switch is turned off. Referring to FIG. 12, the MEMS switch may include four switches: a switch 121, a switch 122, a switch 124, and a switch 125, where the switch 121 and the switch 122 may form a signal transmission path 123, and the switch 124 and the switch 125 may form a signal transmission path 126.

It should be noted that FIG. 11 shows a case where the switch 121, the switch 122, the switch 124, and the switch 125 are single-input single-output switches. In some possible examples, the switch chips may be implemented by a single-input double-output switch or a single-output double-input switch. Still taking FIG. 11 as an example, in this case, the switch 121 and the switch 124 may be implemented by a single-input double-output switch, and the switch 124 and the switch 125 may be implemented by a single-output double-input switch; or the switch 121 and the switch 124 may be implemented by a single-output double-input switch, and the switch 124 and the switch 125 may be implemented by a single-input double-output switch.

It should be further noted that, with reference to two paths with different phase differences shown in FIG. 11, it may be derived from a solution implemented by four single-input single-output switches or one single-input double-output switch and one single-output double-input switch; for a switch phase shift unit having three paths with different phase differences, a solution of using six single-input single-output switches or one single-input three-output switch and one single-output three-input switch may be used; for a switch phase shift unit having four paths with different phase differences, a solution of using eight single-input single-output switches or one single-input four-output switch and one single-output four-input switch may be used. Theoretically, the switch phase shift unit may include more than four paths with different phase differences, and the phase change range of the liquid crystal phase shift unit is [0, 90°], so that the switch phase shift unit may be provided with four paths with different phase differences, for example, {0°, 90°, 180°, 270°}. Of course, in practical applications, with reference to the phase change range of the liquid crystal phase shift unit, the switch phase shift unit may be provided with a corresponding number of paths, for example, when the phase change range of the liquid crystal phase shift unit is [0, 60°], the switch phase shift unit may be provided with six paths with different phase differences, for example, {0°, 60°, 120°, 180°, 240°, 300°}, which can also achieve the effect on phase shift of [0, 360°], and corresponding solutions fall within the protection scope of the present disclosure.

Taking that the MEMS switch is implemented by the membrane structure as an example, referring to FIG. 13, a first end 131 of the membrane structure is electrically connected to a first control line (not shown in the figure), and a second end 132 of the membrane structure is electrically connected to a second control line (not shown in the figure); when a voltage difference exists between the first end 131 and the second end 132 of the membrane structure, a membrane 133 of the membrane structure is deformed to change a signal transmission path. When the membrane 133 of the membrane structure is kept in an original state, the membrane 133 of the membrane structure is turned on, and a signal can pass through a signal transmission line 134; when the membrane 133 of the membrane structure is deformed, the membrane 133 of the membrane structure is turned off, and the signal cannot pass through the signal transmission line 134. In an example, referring to FIG. 14, the MEMS switch may include 4 switches: a switch 141, a switch 142, a switch 144, and a switch 145, where the switch 141 and the switch 142 may form a signal transmission path 143, and the switch 144 and the switch 145 may form a signal transmission path 146.

It can be understood that FIG. 14 shows a solution of two paths with different phase differences, and the switch 141, the switch 142, the switch 144, and the switch 145 may be replaced with a single-input multiple-output switch or a single-output multiple-input switch according to a specific scenario. For details, reference may be made to the contents of the solution shown in FIG. 11, which will not be repeated here.

Based on the above structure, the phase shift range of the liquid crystal phase shifter provided in this embodiment is [0°, 360°], and its division manner may include a manner described as follows.

In an example, a phase shift range of the liquid crystal phase shift unit is [0, 180°], and a phase shift angle of the switch phase shift unit is a value of {0°, 180°}. A block diagram of the liquid crystal phase shifter is shown in FIG. 15, and in this case, functions of the liquid crystal phase shifter are shown in Table 1. Referring to Table 1, a loss of the liquid crystal phase shifter is 2.33 dB, which reduces the loss of the liquid crystal phase shifter.

TABLE 1
Performance of 180° liquid crystal phase shifter and
phase shifter with single-input double-output switch circuit

| | Required | Liquid crystal | Switch phase | |
|---|---|---|---|---|
| Unit | phase | phase shift unit | shift unit | Loss (dB) |
| #1 | 0° | 0° | 0° | 2.3 |
| #2 | 60° | 60° | 0° | 2.3 |
| #3 | 120° | 120° | 0° | 2.3 |
| #4 | 180° | 180° | 0° | 2.3 |
| #5 | 240° | 60° | 180° | 2.33 |
| #6 | 300° | 120° | 180° | 2.33 |
| #7 | 360(0) ° | 0° | 0° | 2.3 |
| #8 | 420(60) ° | 60° | 0° | 2.3 |

It should be noted that [0°, 180°] indicates that a phase is changed between 0° ˜180° (including endpoints), which is a continuous change range; {0°, 180°} indicates that a phase change is 0° or 180°, which is a discrete phase change range, and when the phase change is 0°, the phase change range is 0˜180°, or when the phase change is 180°, the phase change range is 180°˜360°.

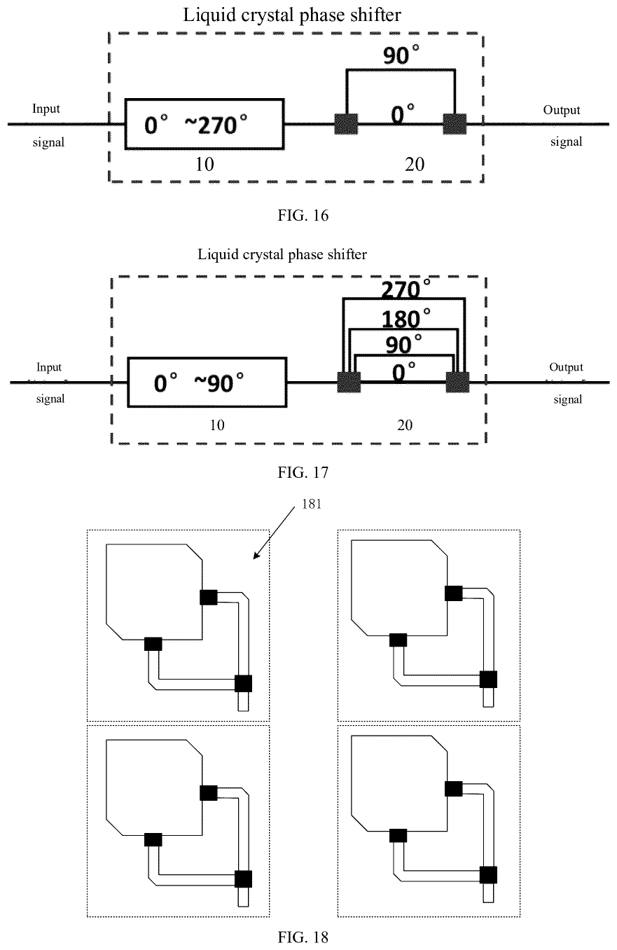

In another example, a phase shift range of the liquid crystal phase shift unit is [0°, 90°], and a phase shift angle of the switch phase shift unit is a value of {0°, 90°, 180°, 270°}. A block diagram of the liquid crystal phase shifter is shown in FIG. 16, and in this case, functions of the liquid crystal phase shifter are shown in Table 2. Referring to Table 2, a maximum loss of the liquid crystal phase shifter in this example is 1.595 dB, which reduces the loss of the liquid crystal phase shifter.

TABLE 2
Performance of 90° liquid crystal phase shifter and
phase shifter with single-input four-output switch circuit

| | Required | Liquid crystal | Switch phase | |
|---|---|---|---|---|
| Unit | phase | phase shift unit | shift unit | Loss (dB) |
| #1 | 0° | 0° | 0° | 1.55 |
| #2 | 60° | 60° | 0° | 1.55 |
| #3 | 120° | 30° | 90° | 1.565 |
| #4 | 180° | 90° | 90° | 1.565 |
| #5 | 240° | 60° | 180° | 1.58 |
| #6 | 300° | 30° | 270° | 1.595 |
| #7 | 360(0) ° | 0° | 0° | 1.55 |
| #8 | 420(60) ° | 60° | 0° | 1.55 |

In yet another example, a phase shift range of the liquid crystal phase shift unit is [0°, 270°], and a phase shift angle of the switch phase shift unit is a value of {0°, 90°}. A block diagram of the liquid crystal phase shifter is shown in FIG. 17.

It should be noted that the embodiments of the liquid crystal phase shifters shown in FIGS. 1 to 17 may be combined with each other without conflict, and obtained solutions fall within the protection scope of the present disclosure.

In this way, in the embodiments, the liquid crystal phase shifter can select the phase change range through the switch phase shift unit, and the liquid crystal phase shift unit can continuously adjust the phase. On the basis of satisfying a phase shift range of [0, 360°] and a higher resolution, a size of the liquid crystal phase shift unit can be reduced, achieving the goal of reducing the loss of the liquid crystal phase shifter.

On the basis of the liquid crystal phase shifter, the embodiments of the present disclosure further provide a phased array antenna. Referring to FIG. 18, the phased array antenna includes radiation devices 181 arranged in an array, and the liquid crystal phase shifters (not shown in FIG. 18) according to FIGS. 1 to 17 respectively corresponding to the radiation devices, where the liquid crystal phase shifters are electrically connected to the radiation devices 181;

Each liquid crystal phase shifter is configured to shift a phase of an input signal to obtain a phase shifted signal.

Each radiation device 181 is configured to receive an electromagnetic wave from a space, convert the electromagnetic wave into a to-be-phase-shifted input signal, and transmit the to-be-phase-shifted input signal to the liquid crystal phase shifter; or the radiation device 181 is configured to convert the phase shifted signal from the liquid crystal phase shifter into an electromagnetic wave signal and radiate the electromagnetic wave signal to a space.

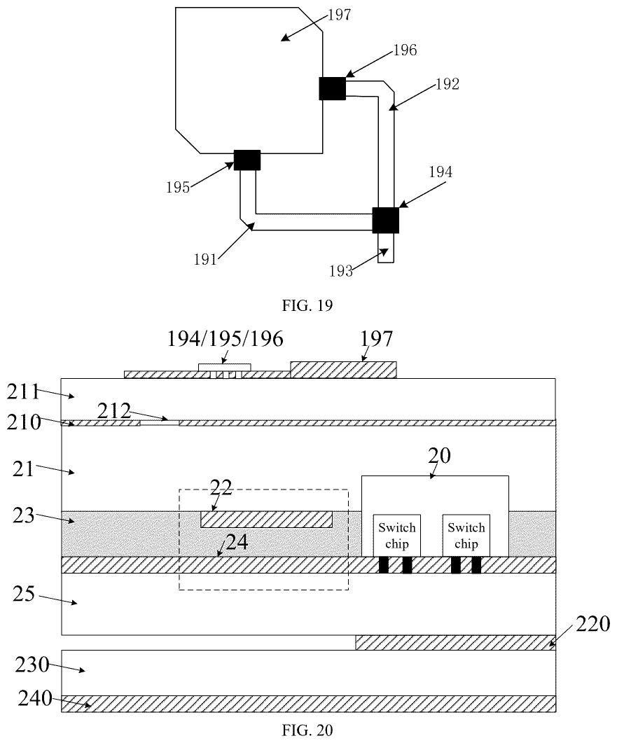

In an embodiment, the radiation device 181 includes a feed selection circuit. When the feed selection circuit is in a first path, a circular polarization direction of the phased array antenna is one of a left-hand direction or a right-hand direction; when the feed selection circuit is in a second path, the circular polarization direction of the phased array antenna is another one of the left-hand direction or the right-hand direction. Referring to FIG. 19, the feed selection circuit includes a first feed line 191, a second feed line 192, a third feed line 193, a first feed switch 194, a second feed switch 195, and a third feed switch 196, where a first end of the first feed switch 194 is electrically connected to the first feed line 191, a second end of the first feed switch 194 is electrically connected to the second feed line 192, and a third end of the first feed switch 194 is electrically connected to the third feed line 193; a first end of the second feed switch 195 is electrically connected to the first feed line 191, and a second end of the second feed switch 195 is electrically connected to a radiation patch 197 of the radiation device 181; a first end of the third feed switch 196 is electrically connected to the second feed line 192, and a second end of the third feed switch 196 is electrically connected to the radiation patch 197.

When the first end and the third end of the first feed switch 194 are electrically connected, and the second feed switch 195 is turned on, the feed selection circuit is in the first path, that is, a signal transmission path of the first path is (taking a radiation signal as an example): the third feed line 193, the first feed switch 194, the first feed line 191, the second feed switch 195, and the radiation patch 197.

When the second end and the third end of the first feed switch 194 are electrically connected, and the third feed switch 196 is turned on, the feed selection circuit is in the second path, that is, a signal transmission path of the second path is (taking a radiation signal as an example): the third feed line 193, the first feed switch 194, the second feed line 192, the third feed switch 196, and the radiation patch 197.

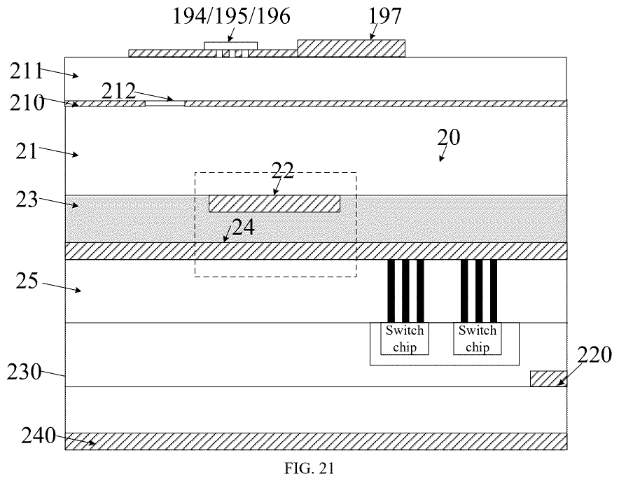

It should be noted that the feed selection circuit is integrally manufactured with the switch phase shift unit in the liquid crystal phase shifter. For example, the feed switches (194, 195, and 196) in the feed selection circuit and the switches of the switch chips in the switch phase shift unit may be formed on a substrate on the same time, so that gate electrodes, source electrodes and drain electrodes of at least a part of the switches are located on the same layer, reducing a number of masking processes. Then, a circuit board of the feed switches in the feed selection circuit and the switch chips in the switch phase shift unit may be cut to form separate circuit units; next, a circuit unit corresponding to the feed selection circuit is made into a radiation device, and a circuit unit corresponding to the switch phase shift unit is made into a liquid crystal phase shifter; and finally, the radiation device may be stacked on the liquid crystal phase shifter to obtain a phased array antenna shown in FIG. 20 or 21.

In an embodiment, referring to FIG. 20, in addition to the liquid crystal phase shifter, the phased array antenna further includes a fourth substrate 211 and a third metal layer 210; the radiation device is arranged on a first side (an upper side shown in FIG. 20) of the fourth substrate 211; the third metal layer 210 is formed on a second side (a lower side shown in FIG. 20) of the fourth substrate 211; the third metal layer 210 is located between the fourth substrate 211 and the first substrate 21 of the liquid crystal phase shifter; a radiation hole 212 is arranged at a position of the third metal layer 210 opposite to the third feed line 193, so that a phase shifted signal output from the liquid crystal phase shifter is radiated to the third feed line 193, or an input signal of the third feed line 193 is radiated to the liquid crystal phase shifter.

Still referring to FIG. 20, a feed network 220 and a fifth substrate 230 are further included, where the feed network 220 is arranged between the fifth substrate 230 and the second substrate 25 of the liquid crystal phase shifter, and is configured to radiate an original signal to the liquid crystal phase shifter for phase shift or receive a phase shifted signal output from the liquid crystal phase shifter. It can be understood that switches in the feed network 220, like those in the liquid crystal phase shifter, may be implemented by a field effect transistor; or in other words, the feed network may be integrally manufactured with the liquid crystal phase shifter, achieving the effect on improving their yield.

Still referring to FIG. 20, a working principle of each unit in the phased array antenna is as follows.

In a transmission stage, the feed network 220 outputs an original signal, and the original signal (or an input signal) is coupled to the second metal layer 24 of the liquid crystal phase shifter, then the original signal is phase shifted through the switch phase shift unit 20 and the liquid crystal phase shift unit 10 in the liquid crystal phase shifter to obtain a phase shifted signal (or an output signal); the phase shifted signal is coupled to a feed path through the radiation hole 212, and is radiated into an electromagnetic wave signal through the radiation patch 197, then the electromagnetic wave signal is radiated to a space. It should be noted that a transmission phase of the radiation patch in each unit needs to be determined according to a beam direction of wave transmitted from the phased array antenna.

In a reception stage, the radiation patch 197 receives the electromagnetic wave signal from the space and obtains the original signal (or the input signal) through the feed path, and the original signal is coupled to the liquid crystal phase shift unit 10 and the switch phase shift unit 20 in the liquid crystal phase shifter through the radiation hole 212 to obtain the phase shifted signal; the phase shifted signal is further coupled to the feed network 220 to complete signal reception.

In another embodiment, referring to FIG. 21, in addition to the liquid crystal phase shifter, the phased array antenna further includes a fourth substrate 211 and a third metal layer 210; the radiation device 181 is arranged on a first side (an upper side shown in FIG. 21) of the fourth substrate 211; the third metal layer 210 is formed on a second side (a lower side shown in FIG. 21) of the fourth substrate 211; the third metal layer 210 is located between the fourth substrate 211 and the first substrate 21 of the liquid crystal phase shifter; a radiation hole 212 is arranged at a position of the third metal layer 210 opposite to the third feed line 193, so that a phase shifted signal output from the liquid crystal phase shifter is radiated to the third feed line 193, or an input signal of the third feed line 193 is radiated to the liquid crystal phase shifter.

Still referring to FIG. 21, a feed network 220 and a fifth substrate 230 are further included, where the feed network 220 is arranged between the fifth substrate 230 and the second substrate 25 of the liquid crystal phase shifter, and is configured to radiate an original signal to the liquid crystal phase shifter for phase shift or receive a phase shifted signal output from the liquid crystal phase shifter. It can be understood that switches in the feed network 220, like those in the liquid crystal phase shifter, may be implemented by a field effect transistor; or in other words, the feed network may be integrally manufactured with the liquid crystal phase shifter, achieving the effect on improving their yield.

Still referring to FIG. 21, the switch chips in the switch phase shift unit of the liquid crystal phase shifter are arranged between the fifth substrate 230 and the second substrate 25, which is different from the disposition of the switch chips in the liquid crystal cell of the liquid crystal phase shift unit in FIG. 2.

Still referring to FIG. 21, a working principle of each unit in the phased array antenna is as follows.

In a transmission stage, the feed network 220 outputs an original signal, and the original signal (or an input signal) is coupled to the second metal layer 24 of the liquid crystal phase shifter, then the original signal is phase shifted through the switch phase shift unit 20 and the liquid crystal phase shift unit 10 in the liquid crystal phase shifter to obtain a phase shifted signal (or an output signal); the phase shifted signal is coupled to a feed path through the radiation hole 212, and is radiated into an electromagnetic wave signal through the radiation patch 197, then the electromagnetic wave signal is radiated to a space. It should be noted that a transmission phase of the radiation patch in each unit needs to be determined according to a beam direction of wave transmitted from the phased array antenna.

In a reception stage, the radiation patch 197 receives the electromagnetic wave signal from the space and obtains the original signal (or the input signal) through the feed path, and the original signal is coupled to the liquid crystal phase shift unit 10 and the switch phase shift unit 20 in the liquid crystal phase shifter through the radiation hole 212 to obtain the phase shifted signal; the phase shifted signal is further coupled to the feed network 220 to complete signal reception.

Other embodiments of the present disclosure will be readily apparent to those skilled in the art after considering the specification and practicing the contents disclosed herein. The present disclosure is intended to cover any variations, uses, or adaptations of the present disclosure, which follow the general principle of the present disclosure and include common knowledge or conventional technical means in the art that are not disclosed in the present disclosure. The specification and examples are to be regarded as illustrative only. The true scope and spirit of the present disclosure are pointed out by the following claims.

It is to be understood that the present disclosure is not limited to the precise structures that have described and shown in the drawings, and various modifications and changes can be made without departing from the scope thereof. The scope of the disclosure is to be limited only by the appended claims.

1. A liquid crystal phase shifter, comprising:
a liquid crystal phase shift unit and a switch phase shift unit, wherein a second end of the liquid crystal phase shift unit is electrically connected to a first end of the switch phase shift unit; wherein a target phase difference between a signal transmitted from a second end of the switch phase shift unit and a signal transmitted from a first end of the liquid crystal phase shift unit is within [0°, 360°]; and
wherein the switch phase shift unit is configured to determine a phase change range of a signal transmitted from the liquid crystal phase shifter;
wherein the liquid crystal phase shift unit is configured to continuously adjust, within the phase change range, a phase of the signal transmitted from the liquid crystal phase shifter to the target phase difference.

2. (canceled)

3. The liquid crystal phase shifter according to claim 1, wherein the liquid crystal phase shift unit comprises a differential liquid crystal phase shifter, and the differential liquid crystal phase shifter comprises a signal synthesizer; wherein the signal synthesizer is configured to synthesize signals respectively transmitted from signal paths of the differential liquid crystal phase shifter to obtain a synthesized signal; and wherein the signals respectively transmitted from the signal paths have a phase difference.

4. (canceled)

5. The liquid crystal phase shifter according to claim 1, wherein the liquid crystal phase shift unit comprises a first substrate, a first metal layer, liquid crystals, a second metal layer and a second substrate that are arranged in sequence; wherein the first metal layer and the second metal layer are opposite to each other, and are configured to continuously adjust a phase of a signal by adjusting directions of the liquid crystals.

6. (canceled)

7. The liquid crystal phase shifter according to claim 5, wherein the first substrate or the second substrate comprises a through hole; wherein the through hole is configured to electrically connect a switch chip of the switch phase shift unit to a pattern portion of the switch phase shift unit; and wherein the pattern portion of the switch phase shift unit is located in a liquid crystal cell of the liquid crystal phase shift unit.

8. (canceled)

9. The liquid crystal phase shifter according to claim 5, wherein the first metal layer comprises a first pattern, and the first pattern comprises first metal wires arranged according to a first direction; the second metal layer comprises a second pattern, and the second pattern comprises second metal wires arranged according to a second direction; wherein the first direction is perpendicular to the second direction; the first metal wires and the second metal wires are opposite to each other; a pattern portion of the switch phase shift unit is arranged on a same layer as the second pattern and is electrically connected to the second pattern through a switch chip of the switch phase shift unit.

10. The liquid crystal phase shifter according to claim 5, wherein the first metal layer comprises a third pattern, and the second metal layer comprises a fourth pattern; and
wherein toothed bars of a first comb-shaped portion of the third pattern and toothed bars of a second comb-shaped portion of the fourth pattern are opposite to each other; wherein a first handle portion of the third pattern and a second handle portion of the fourth pattern form a path with a preset phase difference.

11. The liquid crystal phase shifter according to claim 10, wherein a pattern portion of the switch phase shift unit is on a same layer as the fourth pattern and is electrically connected to the fourth pattern through a switch chip of the switch phase shift unit.

12. The liquid crystal phase shifter according to claim 11, wherein the switch phase shift unit comprises a switch chip attached to the second substrate; wherein the switch chip is configured to select any one path of the pattern portion.

13. The liquid crystal phase shifter according to claim 5, wherein a switch chip of the switch phase shift unit is in a liquid crystal cell of the liquid crystal phase shift unit.

14-15. (canceled)

16. The liquid crystal phase shifter according to claim 13, wherein a groove is at a position of the first substrate corresponding to the switch phase shift unit, and the groove matches the liquid crystal cell.

17. The liquid crystal phase shifter according to claim 13, wherein the liquid crystal phase shift unit comprises a third substrate between the first substrate and the first metal layer; wherein a through hole matching the liquid crystal cell is at a position of the third substrate corresponding to the switch phase shift unit.

18. The liquid crystal phase shifter according to claim 13, wherein a through hole matching the liquid crystal cell is at a position of the first substrate corresponding to the switch phase shift unit.

19-20. (canceled)

21. The liquid crystal phase shifter according to claim 13, wherein the switch chip of the switch phase shift unit is an MEMS switch with a cantilever beam structure; a first end of the cantilever beam structure is electrically connected to a first control line, and a second end of the cantilever beam structure is electrically connected to a second control line; wherein a movable contact of the cantilever beam structure contacts a stationary contact of the cantilever beam structure to change a signal transmission path in response to a voltage difference between the first end and the second end of the cantilever beam structure.

22. The liquid crystal phase shifter according to claim 13, wherein the switch chip of the switch phase shift unit is an MEMS switch with a membrane structure; a first end of the membrane structure is electrically connected to a first control line, and a second end of the membrane structure is electrically connected to a second control line; wherein a membrane of the membrane structure is deformed to change a signal transmission path in response to a voltage difference between the first end and the second end of the membrane structure.

23. The liquid crystal phase shifter according to claim 1, wherein
a phase shift range of the liquid crystal phase shift unit is [0°, 180°], and a phase shift angle of the switch phase shift unit is a value of {0°, 180°}; or
a phase shift range of the liquid crystal phase shift unit is [0°, 90°], and a phase shift angle of the switch phase shift unit is a value of {0°, 90°, 180°, 270°}; or
a phase shift range of the liquid crystal phase shift unit is [0°, 270°], and a phase shift angle of the switch phase shift unit is a value of {0°, 90°}.

24. A phased array antenna, comprising: radiation devices arranged in an array, and liquid crystal phase shifters according to claim 1 respectively corresponding to the radiation devices, wherein the liquid crystal phase shifters are electrically connected to the radiation devices; wherein
each of the liquid crystal phase shifters is configured to shift a phase of an input signal to obtain a phase shifted signal; and
each of the radiation devices is configured to receive an electromagnetic wave from a space, convert the electromagnetic wave into a to-be-phase-shifted input signal, and transmit the to-be-phase-shifted input signal to the liquid crystal phase shifter electrically connected thereto, or each of the radiation devices is configured to convert the phase shifted signal from the liquid crystal phase shifter electrically connected thereto into an electromagnetic wave signal, and radiate the electromagnetic wave signal to a space.

25. The phased array antenna according to claim 24, further comprising: a fourth substrate and a third metal layer, wherein each of the radiation devices is arranged on a first side of the fourth substrate; wherein the third metal layer is on a second side of the fourth substrate; wherein the third metal layer is between the fourth substrate and a first substrate; wherein the third metal layer comprises a radiation hole.

26. The phased array antenna according to claim 24, further comprising, for each of the liquid crystal phase shifters, a feed network and a fifth substrate, wherein the feed network is between the fifth substrate and a second substrate of the liquid crystal phase shifter, and is configured to radiate an original signal to the liquid crystal phase shifter or receive a phase shifted signal output from the liquid crystal phase shifter.

27. The phased array antenna according to claim 25, wherein the radiation device comprises a feed selection circuit.

28. The phased array antenna according to claim 27, wherein the feed selection circuit comprises a first feed line, a second feed line, a third feed line, a first feed switch, a second feed switch, and a third feed switch;
wherein a first end of the first feed switch is electrically connected to the first feed line, a second end of the first feed switch is electrically connected to the second feed line, and a third end of the first feed switch is electrically connected to the third feed line;
wherein a first end of the second feed switch is electrically connected to the first feed line, and a second end of the second feed switch is electrically connected to a radiation patch of the radiation device;
wherein a first end of the third feed switch is electrically connected to the second feed line, and a second end of the third feed switch is electrically connected to the radiation patch;
wherein the radiation hole of the third metal layer is opposite to the third feed line;
wherein the feed selection circuit is in the first path in response to the first end and the third end of the first feed switch being electrically connected and the second feed switch turned on and the feed selection circuit is in the second path in response to the second end and the third end of the first feed switch being electrically connected and the third feed switch turned on.

29-30. (canceled)
